(19) United States
(12) Patent Application Publication
(10) Pub. No.: US 2003/0049935 A1
(43) Pub. Date: Mar. 13, 2003

(54) Method for removing residual particles from a polished surface

(75) Inventors: Hou-Hong Chou, Taipei (TW); Jiun-Fang Wang, Hsinchu (TW)

Correspondence Address: BIRCH STEWART KOLASCH & BIRCH, PO BOX 747, FALLS CHURCH, VA, 22040-0747, US

(73) Assignee: PROMOS TECHNOLOGIES INC.

(21) Appl. No.: 10/218,626

(22) Filed: Aug. 15, 2002

Related U.S. Application Data
(63) Continuation-in-part of application No. 09/848,254, filed on May 4, 2001, now abandoned.

(51) Int. Cl. H01L 21/302; H01L 21/461

(52) U.S. Cl. 438/692; 438/745

(57) ABSTRACT

The present invention provides a method of removing residual particles from a polished surface. The method comprises the steps of: providing a substrate, forming a dielectric layer on the substrate, brush-cleaning and etching the dielectric layer on the substrate with a liquid when residual particles are lodged therein, whereby the residual particles are loosened and then relocated to the dielectric layer, and finally cleaning the dielectric layer to remove the relocated residual particles.

### BACKGROUND OF THE INVENTION

1. Field of the Invention

The present invention relates to a method for removing residual particles from a polished surface and particularly to a method for removing residual ceria or zirconia particles from a polished wafer surface.

2. Description of the Prior Art

Currently, Chemical-Mechanical Polishing (CMP) is the most popular global planarization method for VLSI or even for ULSI. During a CMP planarization process, a reagent or slurry is provided onto a polishing table while a wafer is rubbed against a polishing pad thereon. Thus, the wafer is polished by the mechanical friction and chemical reaction between the wafer and the pad.

Some residual particles might remain on the surface of the polished wafer after polishing. They might be from the slurry or the pad. A process for removing those particles is needed in order to protect the wafer from damaging by the particles. The first step of this process is cleaning, such as brush cleaning, spray cleaning and ultrasonic cleaning. During brush cleaning, for example, the wafer is rinsed with a chemical liquid and brushed with a PVA brush at the same time. Most of the particles are removed at the first step.

The rest of the particles will be removed during a second step, the particle removing process. The procedure is to dip the wafer into a wet bench containing a liquid mixture of H₂O₂ and NH₄OH or H₂O₂ and HCl. The particles are removed and remain in the wet bench.

FIG. 1 is a flow chart of a traditional method for removing residual particles on a wafer polished with a slurry containing silicon or aluminum. First, in step 11, the wafer is brush-cleaned with a DI water or NH₄OH liquid. The DI water or NH₄OH liquid increases the surface potential of the residual particles, which makes the repulsive forces between the particles and the wafer surface strong enough for separation. Together with the mechanical force provided by the brush, most of the particles are removed from the wafer surface.

Second, in step 12, the wafer is dipped into a wet bench containing a liquid mixture of H₂O₂ and NH₄OH or H₂O₂ and HCl. The rest of the particles are removed and remain in the wet bench. Most recently, a new approach to STI CMP has been developed through the use of 3M's Slurry Free™ Fixed Abrasive Technology (J. Gagliardi, T. Vo, “STI Polishing with 3M's Fixed Abrasive”, 1999 VMIC 16^{th} International VLSI Multilevel Interconnection Cof., Sep. 6˜9, 1999, J. Gagliardi, “3M Fixed Abrasive CMP Polishing of Semiconductor Oxide Films”, 3M Internal Pub., September, 1999, E. Funkenbusch, “Slurry Free Oxide CMP Techniques”, 3M, Semicon West, 1998, and P. Van der Velden, “Chemical Mechanical Polishing Using Fixed Abrasives”, SEMI Europa, 1998, A. Ssthuraman, W. Koutny, E. Shamble, “Comparison of Defectivity Between Slurry-Based and SlurryFree Dielectric CMP”, Cypress, Scmicon, CMPUG, Dec. 3, 1998.). A unique combination of microreplication, coated abrasive and particle science technologies has resulted in a Fixed Abrasive capable of CMP. Small composites (i.e, 200 μm wide and 40 μm high) of abrasive (CeO₂) and resin binder are positioned on a polyester backing. The composites are precisely shaped and provide a third dimension of abrasive, as well as considerable space for chemical and by-product transport. Rather than continuously having to supply fresh abrasive to the pad via slurry, and pad conditioning, the Fixed Abrasive matrix contains all the necessary abrasive. No conditioning is required. The only chemistry necessary is pH-adjusted wafer to meet polish rate requirements. The Fixed Abrasive is designed so that topological wafers microcondition the abrasive composites to expose fresh mineral during polishing. A key advantage of CMP using Fixed Abrasive over conventional polishing method is its selectivity to topography (often>100:1). Unless a selective chemical is used the selectivity between oxide and nitride is on the order of 1:1[1, 2, 3]. This provides a polishing system that rapidly planarizes, and is not susceptible to dishing upon overpolish.

The traditional removing method can successfully remove residual particles when applied to wafers polished with a slurry containing silicon or aluminum. However, slurries or pads containing cerium or zirconium are gaining more and more popularity due to their high polishing efficiency. The removal mechanism for ceria or zirconia particles is much different from that of silica or alumina particles. The traditional method can not be successfully applied, particularly to fixed abrasive polish wherein the ceria or zirconia residual particles may even be lodged in the wafer. The brush cleaning in step 11 of FIG. 1 can only successfully remove the particles on the wafer surface, not those actually lodged within the wafer. Dipping the wafer into the wet bench may remove the lodged particles but will therefore be harmful to the wet bench, and many particles are still not removed.

### SUMMARY OF THE INVENTION

The object of the present invention is to solve the above-mentioned problems and to provide a method of removing residual particles from a polished surface which can be applied to the fixed abrasive polish using pads containing cerium or zirconium.

To achieve the above-mentioned object, the method of removing residual particles from a polished surface comprises the steps of: providing a substrate, forming a dielectric layer on the substrate, brush-cleaning and etching the dielectric layer on the substrate with a liquid when the residual particles are lodged in the dielectric layer, whereby the residual particles are loosened and then relocated on the dielectric layer and further cleaning the dielectric layer to remove the relocated residual particles thereon.

In the present invention, the dielectric layer on the substrate is brush-cleaned and etched at the same time. Thus the lodged particles are loosened and relocated to the surface of the dielectric layer.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1 is a flow chart of a traditional method for removing residual particles on a wafer polished with a slurry containing silicon or aluminum.

FIG. 2 is a flow chart of a method for removing residual particles on a polished wafer according to one embodiment of the invention.

FIG. 3A˜3C are cross-sectional views of a wafer processed by the method for removing residual particles on a polished wafer according to one embodiment of the invention.

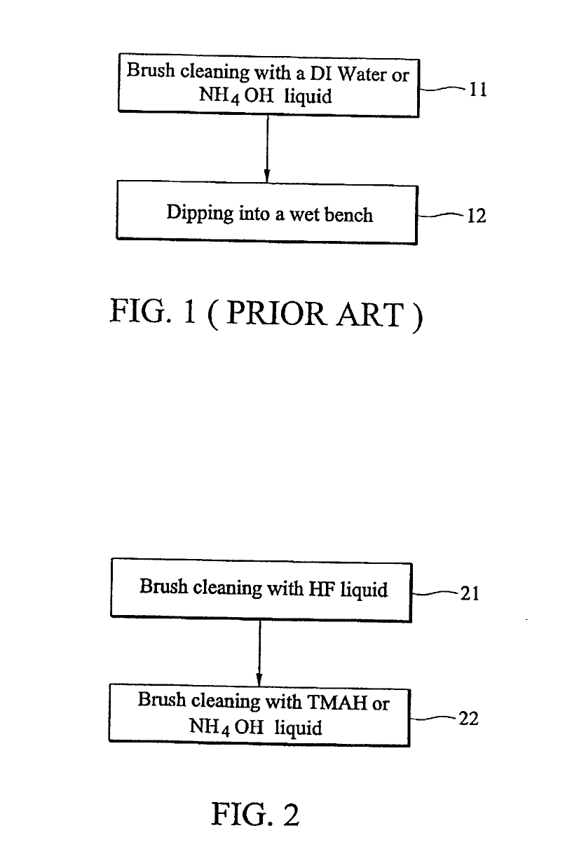

### DETAILED DESCRIPTION OF THE INVENTION

FIG. 2 is a flow chart of a method for removing residual particles on a polished wafer according to one embodiment of the invention. First, in the step 21, a semiconductor substrate (e.g. a silicon wafer) with a polished dielectric layer (e.g. a silicon oxide or silicon nitride layer) thereon is brush-cleaned for 30 seconds with an acid liquid, such as a hydrofluoric acid liquid with a concentration of 1% in weight. The dielectric layer has been fixed-abrasive-polished with ceria or zirconia oxide pad.

Next, in step 22, the substrate with the dielectric layer is further brush-cleaned for 20˜30 seconds with a alkaline liquid, such as a TMAH liquid with a concentration of 2.38% in weight, a NH₄OH liquid with a concentration of 2% in weight or a mixed liquid of both.

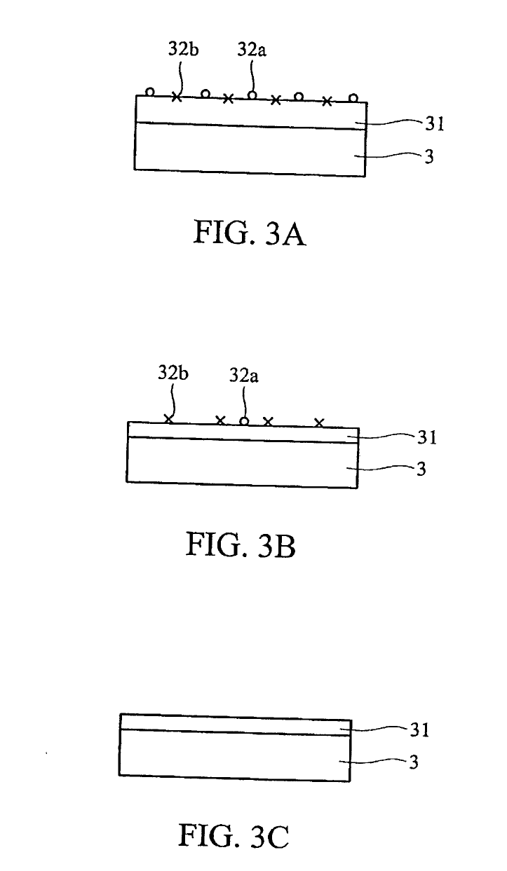

FIG. 3A˜3C are cross-sectional views of a wafer processed by the method for removing residual particles on a polished wafer according to one embodiment of the invention.

Please refer to FIG. 3A. A silicon wafer 3 with a silicon oxide layer 31 has been fixed-abrasive-polished with a ceria oxide pad. The resulting residual particles (particles of ceria oxide) 32a and 32b are attach to and become lodged in the silicon oxide layer 31, respectively.

Please refer to FIG. 3B. which shows the silicon wafer 3 with a silicon oxide layer 31 being brush-cleaned with a hydrofluoric acid liquid, as in step 21 of FIG. 2. A depth of more than 30 Å of the silicon oxide layer is etched by the hydrofluoric acid liquid. Together with the mechanical force provided by the brush, the ceria oxide particles 32a and 32b are loosened from the silicon oxide layer 31. Therefore, some of the ceria oxide particles 32a and 32b are relocated to the surface of the silicon oxide layer 31 and the others are removed from the wafer 3.

Please refer to FIG. 3C. The silicon wafer 3 with the silicon oxide layer 31 is further brush-cleaned for 20˜30 seconds with a liquid mixture of TMAH liquid with a concentration of 2.38% in weight and NH₄OH liquid with a concentration of 2% in weight, as step 22 of FIG. 2. Since the ceria oxide particles 32a and 32b are relocated to the surface of the wafer 3 and none of them are lodged, they can now only be removed from the wafer 3 by brush cleaning.

The validity of the above method has been proven in one experiment. The original number of the residual particles was 804. After the first brush cleaning step, 304 were removed and 490 were relocated. When the second brush cleaning step was finished, there were only 30˜40 residual particles remaining on the wafer surface. The residual particles were thus successfully removed.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method for removing residual particles trapped in a dielectric layer, the method comprising the steps of:
providing a semiconductor substrate;
forming the dielectric layer on the semiconductor substrate;
processing the dielectric layer on the semiconductor substrate by fixed abrasive polish, which generates the residual particles trapped in the dielectric layer;
brush-cleaning and etching the dielectric layer on the semiconductor substrate with a hydrofluoric acid liquid to loosen and relocate the residual particles trapped in the dielectric layer to a surface of the dielectric layer; and
further cleaning the dielectric layer with a TMAH liquid to remove the residual particles from the surface of the dielectric layer.

2. The method as claimed in claim 1, wherein the residual particles are selected from a group comprising particles of ceria oxide and particles of zerconia oxide.

3. The method as claimed in claim 1, wherein the dielectric layer is selected from a group comprising a silicon oxide layer and a silicon nitride layer.

4. The method as claimed in claim 1 wherein the concentration of the hydrofluoric acid solution is 1% in weight.

5. The method as claimed in claim 1, wherein the dielectric layer is brush-cleaned and etched with the hydrofluoric acid liquid for 30 seconds.

6. The method as claimed in claim 1, wherein a depth more than 30 Å of the dielectric layer is etched by the hydrofluoric acid liquid.

7. The method as claimed in claim 1, wherein the dielectric layer is further cleaned by brush-cleaning with the TMAH liquid for 20˜30 seconds.

8. The method as claimed in claim 12, wherein the concentration of the TMAH solution is 2.38% in weight.

9. A method for removing residual particles trapped in a dielectric layer, the method comprising the steps of:
providing a semiconductor substrate;
forming the dielectric layer on the semiconductor substrate;
processing the dielectric layer on the semiconductor substrate by fixed abrasive polish, which generates the residual particles trapped in the dielectric layer;
brush-cleaning and etching the dielectric layer on the semiconductor substrate with a hydrofluoric acid liquid to loosen and relocate the residual particles trapped in the dielectric layer to a surface of the dielectric layer; and
further cleaning the dielectric layer with a NH₄OH liquid to remove the residual particles from the dielectric layer.

10. The method as claimed in claim 9, wherein the residual particles are selected from a group comprising particles of ceria oxide and particles of zerconia oxide.

11. The method as claimed in claim 9, wherein the dielectric layer is selected from a group comprising a silicon oxide layer and a silicon nitride layer.

12. The method as claimed in claim 9 wherein the concentration of the hydrofluoric acid solution is 1% in weight.

13. The method as claimed in claim 9, wherein the dielectric layer is brush-cleaned and etched with the hydrofluoric acid liquid for 30 seconds.

14. The method as claimed in claim 9, wherein a depth more than 30 Å of the dielectric layer is etched by the hydrofluoric acid liquid.

15. The method as claimed in claim 9, wherein the dielectric layer is further cleaned by brush-cleaning with the NH₄OH liquid for 20˜30 seconds.

16. The method as claimed in claim 9, where in the concentration of the NH₄OH liquid is 2% in weight.

17. A method for removing residual particles trapped in a dielectric layer, the method comprising the steps of:
providing a semiconductor substrate;
forming the dielectric layer on the semiconductor substrate;
processing the dielectric layer on the semiconductor substrate by fixed abrasive polish, which generates the residual particles trapped in the dielectric layer;
brush-cleaning and etching the dielectric layer on the semiconductor substrate with a hydrofluoric acid liquid to loosen and relocate the residual particles trapped in the dielectric layer to a surface of the dielectric layer; and
further cleaning the dielectric layer with a mixed liquid of a TMAH and NH₄OH liquid to remove the residual particles from the dielectric layer.

18. The method as claimed in claim 17, wherein the residual particles are selected from a group comprising particles of ceria oxide and particles of zerconia oxide.

19. The method as claimed in claim 17, wherein the dielectric layer is selected from a group comprising a silicon oxide layer and a silicon nitride layer.

20. The method as claimed in claim 17 wherein the concentration of the hydrofluoric acid solution is 1% in weight.

21. The method as claimed in claim 17, wherein the dielectric layer is brush-cleaned and etched with the hydrofluoric acid liquid for 30 seconds.

22. The method as claimed in claim 17, wherein a depth more than 30 Å of the dielectric layer is etched by the hydrofluoric acid liquid.

23. The method as claimed in claim 17, wherein the dielectric layer is further cleaned by brush-cleaning with the mixed liquid of the TMAH and NH₄OH liquid for 20˜30 seconds.

24. The method as claimed in claim 17, wherein the mixed liquid is made by mixing the TMAH and the NH₄OH liquid with concentrations of 2.38% and 2% in weight, respectively.
